(19) United States
(12) Patent Application Publication
(10) Pub. No.: US 2009/0146135 A1
(43) Pub. Date: Jun. 11, 2009

(54) DETECTOR AND METHOD OF FABRICATING THE SAME

(75) Inventors: Seong Hyun Kim, Daejeon (KR); Yong Suk Yang, Daejeon (KR); Sang Chul Lim, Daejeon (KR); Zin Sig Kim, Daejeon (KR); Yoon Ho Song, Daejeon (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon (KR)

(21) Appl. No.: 12/181,845

(22) Filed: Jul. 29, 2008

(30) Foreign Application Priority Data
Dec. 5, 2007 (KR) 10-2007-0125544

(51) Int. Cl. H01L 51/05; H01L 51/40

(52) U.S. Cl. 257/40; 438/49; 257/E51.005

(57) ABSTRACT

Provided are a detector and a method of fabricating the same. The detector includes a base portion; first and second electrodes disposed on the base portion and spaced apart from each other; a reactant layer disposed between the first and second electrodes on the base portion to react with a specific functional group contained in a fluid; and a protection medium layer surrounding the first and second electrodes and forming a reaction space to expose a portion of the reactant layer. In the detector, electrodes can be effectively protected at low cost, and a path for guiding a fluid to be detected can be provided.

### CROSS-REFERENCE TO RELATED APPLICATION

This application claims priority to and the benefit of Korean Patent Application No. 2007-125544, filed Dec. 5, 2007, the disclosure of which is incorporated herein by reference in its entirety.

### BACKGROUND

1. Field of the Invention

The present invention relates to a detector for detecting a specific functional group contained in a fluid and, more specifically, to a detector corresponding to a bio-device formed of an organic semiconductor, which is fabricated using a semiconductor fabrication process and detects a specific chemical functional group contained in a fluid, and a method of fabricating the same.

2. Discussion of Related Art

Conventionally, a detector is formed using an inorganic semiconductor. An electrode portion is then protected using an organic material, such as polydimethylsiloxane (PDMS), and a bio-solution is flowed on a semiconductor portion to measure the characteristics of the semiconductor portion.

In this case, however, because the fabrication of the detector is costly, the detector is not appropriate as a disposable or portable detector. Accordingly, it is necessary to develop an ultra-low-cost detector which can be fabricated using a printing technique, such as an inkjet printing technique, and can easily measure the characteristics of a semiconductor.

Accordingly, a semiconductor detector using an organic semiconductor as ink has been proposed so as to reduce fabrication costs. However, in order to detect a specific protein or carbohydrate, a bio-solution, such as blood, has to be applied on the semiconductor detector to measure the electrical characteristics of the semiconductor detector. However, a variation in current flowing through the bio-solution may be greater than a variation in the electrical characteristics of the semiconductor detector caused by a variation in the characteristics of the semiconductor detector. In this case, the characteristics of the semiconductor detector may not be precisely measured.

### SUMMARY OF THE INVENTION

The present invention is directed to a detector that may be fabricated at low cost using a semiconductor fabrication process.

Also, the present invention is directed to a detector that is superior in detection performance to conventional detectors.

One aspect of the present invention provides a detector including: a base portion; first and second electrodes disposed on the base portion and spaced apart from each other; a reactant layer disposed between the first and second electrodes on the base portion to react with a specific functional group contained in a fluid; and a protection medium layer surrounding the first and second electrodes and forming a reaction space to expose a portion of the reactant layer.

Another aspect of the present invention provides a method of fabricating a detector. The method includes: forming a lower substrate having a reactant layer which reacts with a specific functional group contained in a fluid; forming an upper substrate having first and second electrodes for measuring electrical characteristics and a protection medium layer for protecting the first and second electrodes; and bonding the upper substrate to the lower substrate.

A detector according to the present invention has a similar structure to a metal-oxide-semiconductor (MOS) transistor. In other words, the detector includes electrodes corresponding to a gate electrode, a source electrode, and a drain electrode of the MOS transistor. Since the detector has the similar structure to the MOS transistor, a charge transmission channel may be formed in a region overlapping an electrode corresponding to the gate electrode. A reactant that reacts with a specific functional group is disposed in a position corresponding to the charge transmission channel.

Typically, an organic semiconductor is used as the reactant. The organic semiconductor has semiconductor characteristics before the organic semiconductor is bonded to the functional group, while the organic semiconductor exhibits similar characteristics to an insulator after the organic semiconductor is bonded to the functional group. A variation in the characteristics of the reactant disposed in the channel of the detector according to the present invention may be easily detected by measuring a variation in electrical characteristics between source and drain electrodes.

In the present invention, a polymer protection layer, such as a polydimethylsiloxane (PDMS) layer, may be formed on the source and drain electrodes of the detector in order to prevent a fluid to be detected from directly contacting the source and drain electrodes of the detector. Furthermore, the polymer protection layer may function as a path for guiding the fluid to the reactant.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view of a detector having a typical organic semiconductor transistor;

FIG. 2 is a cross-sectional view of a detector according to an exemplary embodiment of the present invention;

FIGS. 3A through 3E are cross-sectional views illustrating a method of fabricating the detector shown in FIG. 2;

FIG. 4 is a cross-sectional view of a detector according to another exemplary embodiment of the present invention;

FIGS. 5A through 5E are cross-sectional views illustrating a method of fabricating the detector shown in FIG. 4;

FIG. 6 is a cross-sectional view illustrating a process of stripping a capping layer from the detector shown in FIG. 4; and

FIG. 7 is a cross-sectional view illustrating a process of injecting a solution to be detected into the detector shown in FIG. 4.

### DETAILED DESCRIPTION OF EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein.

Initially, a basic structure of a detector using a typical organic semiconductor transistor will be described with reference to FIG. 1.

The organic semiconductor transistor may be fabricated using a portion of a silicon substrate, which is heavily doped with a P-type or N-type dopant, as a gate. Alternatively, as shown in FIG. 1, a gate electrode 12′ may be formed on a silicon substrate (not shown), and a dielectric layer 20′ may be formed as an insulating layer on the gate electrode 12′. In this case, each of the gate electrode 12′ and the dielectric layer 20′ may be formed of an organic material and/or an inorganic material. An organic semiconductor layer 30′ is formed on the dielectric layer 20′.

The organic semiconductor may contain a component that is bonded to a bio-molecule, such as a specific protein or carbohydrate. For example, the organic semiconductor may be poly-3-hexylthiophene (P3HT) or poly(9,9-dioctylfluorene-co-bithiophene) (P8T2), and when biotin is bonded to a side chain of P3HT or P8T2, the organic semiconductor is strongly bonded to avidin protein. The organic semiconductor has semiconductor characteristics before the organic semiconductor is bonded to the avidin protein, while the organic semiconductor exhibits similar characteristics to an insulator after the organic semiconductor is bonded to the avidin protein. Thus, it may be detected whether a specific protein is contained in a bio-solution depending on a variation in the electrical characteristics of the organic semiconductor. In other words, the avidin protein becomes a functional group to be detected. Therefore, after an organic semiconductor is bonded to the functional group, the presence or absence of a specific protein may be detected by measuring a variation in the electrical characteristics of the organic semiconductor.

### Embodiment 1

FIG. 2 is a cross-sectional view of a detector according to an exemplary embodiment of the present invention.

Referring to FIG. 2, a gate electrode layer 12 corresponding to a third electrode layer is provided. A dielectric layer 20 is disposed as an insulating layer on the gate electrode layer 12. Source and drain electrodes 10 and 11 are disposed respectively as first and second electrodes on the dielectric layer 20 and spaced apart from each other. An organic semiconductor layer 30 is disposed between the source and drain electrodes 10 and 11 on the dielectric layer 20. The organic semiconductor layer 30 functions as a reactant layer that reacts with a specific functional group contained in a fluid. A polymer layer, specifically, a PDMS layer 40, is disposed to surround the source and drain electrodes 10 and 11. The PDMS layer 40 is a protection medium layer that forms a slot-type conduit 60 functioning as a reaction space to partially expose the organic semiconductor layer 30.

The gate electrode layer 12 and the dielectric layer 20 may form a base portion. Also, the base portion may further include a frame layer that provides mechanical intensity. The frame layer may be a silicon wafer, which is used to fabricate a detector using a semiconductor fabrication technique. Alternatively, the frame layer may be formed of glass or plastic.

The gate electrode layer 12, the source electrode 10, and the drain electrode 11 may constitute a transistor having a similar structure to a metal-oxide-semiconductor (MOS) transistor. Thus, the presence or absence and/or amount of a material molecule to be detected may be estimated by measuring electrical characteristics (e.g., voltage, current, and resistance) between the source and drain electrodes 10 and 11.

Each of the gate electrode layer 12, the source electrode 10, and the drain electrode 11 may be formed of a conductive material to function as an electrode. For example, each of the gate electrode layer 12, the source electrode 10, and the drain electrode 11 may be formed of at least one of an organic material and an inorganic material.

The organic semiconductor layer 30 may be formed of an organic semiconductor. The organic semiconductor may contain a component that is bonded to a bio-molecule to be detected, such as a specific protein or carbohydrate. For example, the organic semiconductor may be poly-3-hexylthiophene (P3HT) or poly(9,9-dioctylfluorene-co-bithiophene) (P8T2).

In the structure shown in FIG. 2, the PDMS layer 40 may effectively protect a region (esp., the source and drain electrodes 10 and 11) other than a portion where a reaction required for the detection of the bio-molecule occurs. In other words, it may be concluded that the PDMS layer 40 functions not only as an electrode protection layer but also as a path for guiding a fluid to be measured.

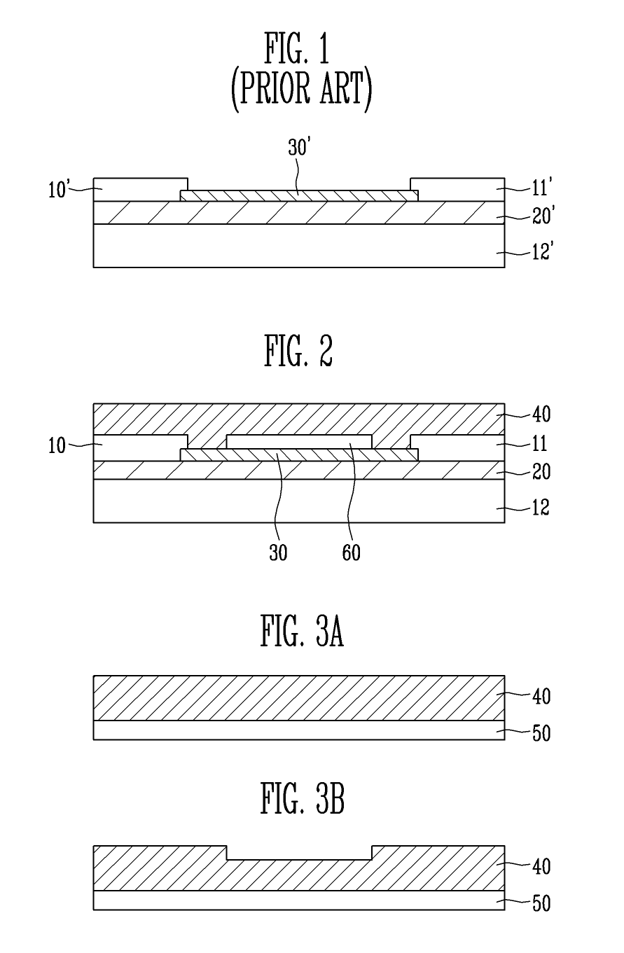

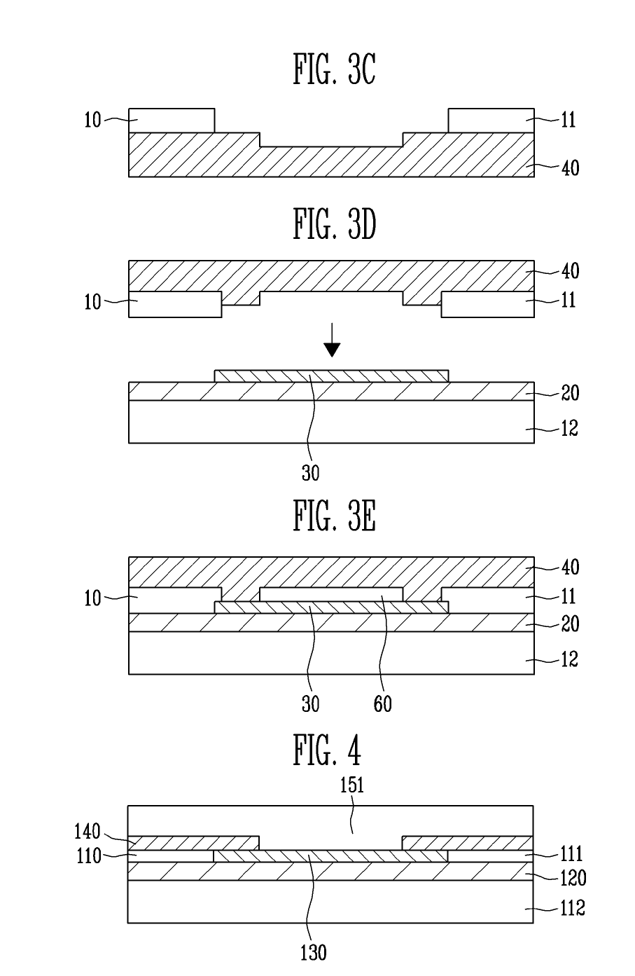

FIGS. 3A through 3E are cross-sectional views illustrating a method of fabricating a detector in which an electrode protection layer and a reaction space are formed of PDMS.

In the present embodiment, the fabrication of the detector includes: forming a lower substrate having a reactant layer that reacts with a specific functional group contained in a fluid; forming an upper substrate having first and second electrodes for measuring electrical characteristics and a protection medium layer for protecting the first and second electrodes; and bonding the upper and lower substrates to each other.

The formation of the upper substrate may include: depositing the protection medium layer on a frame layer; forming a reaction space pattern in the protection medium layer; and forming an electrode on a portion of the protection medium layer.

Hereinafter, a process of forming the upper substrate using the protection medium layer formed of PDMS will be described in detail.

Referring to FIG. 3A, a PDMS layer 40 corresponding to the protection medium layer is formed on the frame layer (not shown).

Referring to FIG. 3B, a gap pattern having a desired shape may be formed using a mold in the PDMS layer 40. The gap pattern will form a reaction space during a subsequent process. Thereafter, the PDMS layer 40 having the gap pattern is detached from the frame layer.

Referring to FIG. 3C, a source electrode 10 and a drain electrode 11 corresponding to the first and second electrodes are formed on the PDMS layer 40 having the gap pattern. In a variation of the present embodiment, the frame layer may be remained.

The formation of the lower substrate shown in FIG. 3D may include forming a gate electrode layer 12; forming a dielectric layer 20 corresponding to an insulating layer on the gate electrode layer 12; and forming an organic semiconductor layer 30 corresponding to the reactant layer on a portion of the dielectric layer 20.

Referring to FIG. 3D, the lower substrate having the gate electrode 12, the dielectric layer 20, and the organic semiconductor layer 30 is bonded to the upper substrate having the PDMS layer 40 with the gap pattern, the source electrode 10, and the drain electrode 11, thereby completing the fabrication of an organic semiconductor detector shown in FIG. 3E. In this case, the upper and lower substrates may be bonded to each other using a semiconductor fabrication process, such as a lamination process.

After the bonding process is finished, a slot-type conduit 60 corresponding to the reaction space is formed by the gap pattern of the upper substrate and the organic semiconductor layer 30 of the lower substrate between the organic semiconductor layer 30 and the PDMS layer 40.

A detection process using the organic semiconductor detector shown in FIG. 3E will now be described.

The detector according to the present embodiment includes the slot-type conduit 60 in which a first wide wall is formed of an organic semiconductor and a second wide wall and both narrow walls are formed of PDMS. One or two drops of a solution to be detected may be dropped in an inlet of the slot-type conduit 60, or the inlet of the slot-type conduit 60 may be dipped in the solution, so that the slot-type conduit 60 may be filled with the solution by capillarity. As a result, the organic semiconductor that forms one wall of the slot-type conduit 60 is sufficiently brought into contact with the solution to cause a sufficient reaction of the organic semiconductor with a functional group to be detected.

Thereafter, the presence or absence and/or amount of a functional group contained in the solution may be detected by measuring electrical characteristics between the source and drain electrodes 10 and 11.

### Embodiment 2

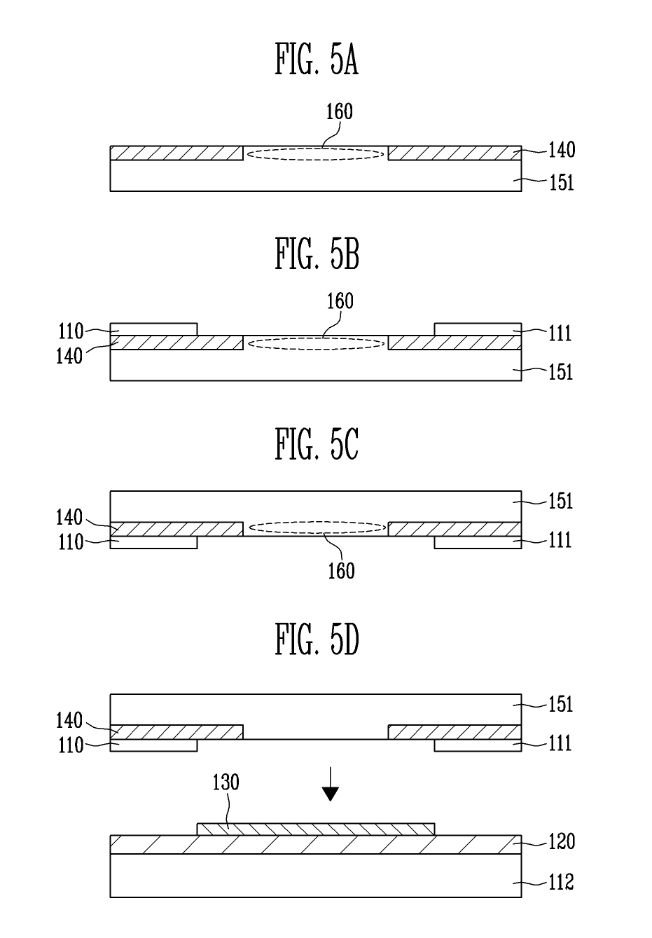

FIG. 4 is a cross-sectional view of a detector according to another exemplary embodiment of the present invention.

Referring to FIG. 4, a gate electrode layer 112 corresponding to a third electrode layer is provided. A dielectric layer 120 is disposed on the gate electrode layer 112. Source and drain electrodes 110 and 111 are disposed as first and second electrodes on the dielectric layer 120 and spaced apart from each other. An organic semiconductor layer 130 is disposed between the source and drain electrodes 110 and 111 on the dielectric layer 120. The organic semiconductor layer 130 functions as a reactant layer that reacts with a specific functional group contained in a fluid. A PDMS layer 140 is disposed to surround the source and drain electrodes 110 and 111. The PDMS layer 140 is a protection medium layer that forms a groove corresponding to a reaction space so as to partially expose the organic semiconductor layer 130. A capping layer 151 is formed on the PDMS layer 140. In a variation of the present embodiment, the capping layer 151 may be omitted.

The components of the detector shown in FIG. 4 are the same as those shown in FIG. 2 except for the shape of the groove and the capping layer 151 and thus, a repeated description thereof will be omitted.

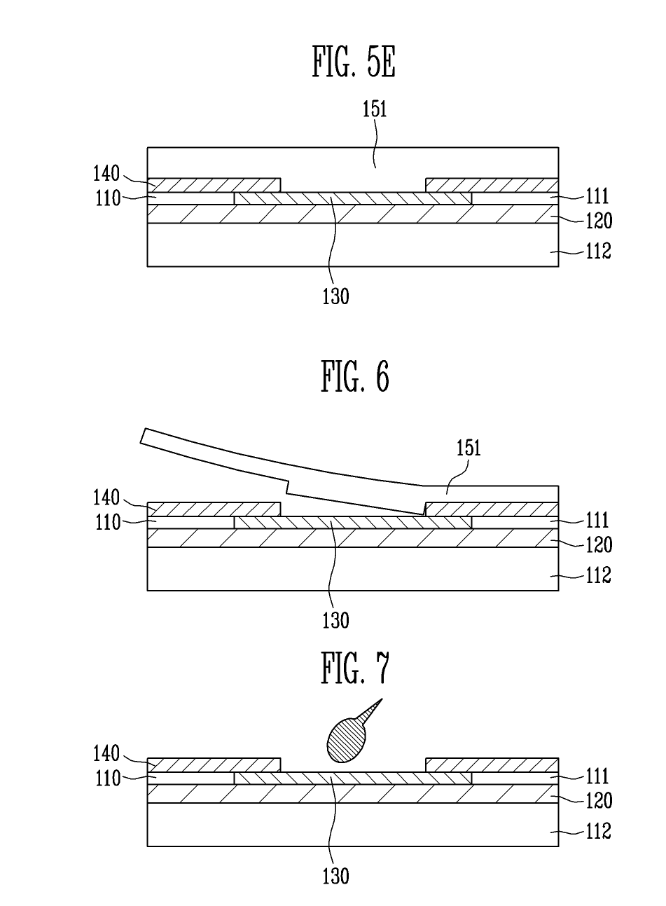

FIGS. 5A through 5E are cross-sectional views illustrating a method of fabricating the detector shown in FIG. 4.

In the present embodiment, the fabrication of the detector includes: forming a lower substrate having a reactant layer that reacts with a specific functional group in a fluid; forming an upper substrate having first and second electrodes for measuring electrical characteristics and a protection medium layer for protecting the first and second electrodes; and bonding the upper substrate to the lower substrate. A capping layer may function as a mold during the fabrication of the detector and be formed of silicon, rubber, or one of other various materials.

The formation of the upper substrate may include: forming a capping layer 151 having a protrusion 160; forming a PDMS layer 140 corresponding to the protection medium layer on a region of the capping layer 151 other than the protrusion 160; and forming source and drain electrodes 110 and 111 corresponding to the first and second electrodes on a portion of the PDMS layer 140.

When the capping layer 151 is removed during a subsequent process, the protrusion 160 is used to form a reaction groove corresponding to a reaction space into which a fluid to be detected is injected.

The capping layer 151 must be removed before the fabrication of the detector is completed or the use of the detector. Thus, when the capping layer 151 is deposited on the PDMS layer 140 corresponding to the protection medium layer, an additional treatment may be performed to facilitate the detachment of the capping layer 151 from the PDMS layer 140. For example, an impurity material layer may be interposed between the PDMS layer 140 and the capping layer 151 to prevent reinforcement of adhesion of the capping layer 151 to the PDMS layer 140.

Since the formation of the lower substrate is the same as in the previous embodiment, a description thereof will be omitted here.

The upper and lower substrates may be bonded to each other using a lamination process. Although the PDMS layer 140 is exemplarily illustrated and described as the protection medium layer, the PDMS layer 140 may be replaced by another polymer layer.

A detection process using the organic semiconductor detector shown in FIG. 5E will now be described.

The detector according to the present embodiment includes a groove having a bottom surface formed of an organic semiconductor. The capping layer 151, which prevents the contamination of the exposed surface of the organic semiconductor layer 130, has to be stripped as shown in FIG. 6 before the detector enters into the detection process. After the capping layer 151 is removed, when a solution to be detected is dropped on the groove as shown in FIG. 7, a top surface of the organic semiconductor layer 130 is sufficiently brought into contact with the solution to cause a sufficient reaction of an organic semiconductor with a functional group to be detected. Thereafter, the presence or absence and/or amount of a functional group contained in the solution may be detected by measuring electrical characteristics between the source and drain electrodes 110 and 111.

In the above-described methods, electrodes and a semiconductor layer can be effectively protected, and a solution to be detected can be effectively injected into only an organic semiconductor portion.

According to the present invention as described above, electrodes can be effectively protected at low cost, and a path for guiding a fluid to be detected can be provided.

Also, a detector according to the present invention can be fabricated at low cost, have improved detection precision, and be convenient to use.

Specifically, the fabrication of a detector according to the present invention involves forming a PDMS layer having a gap pattern on an organic semiconductor sensor, thereby forming a path for guiding a bio-solution to be detected. Therefore, electrodes can be effectively protected from a solution to be detected, and the organic semiconductor sensor can be effectively protected from air or moisture. In addition, since an upper substrate having the electrodes is laminated on a lower substrate having the organic semiconductor sensor, the electrodes are not restricted in sizes.

Furthermore, a structure required for forming the path can function as an electrode protection layer, and a final detector can be fabricated using a lamination process, thereby greatly reducing the fabrication cost of the detector.

When electrodes are formed on an organic semiconductor layer, a wet process cannot be performed because of the damage to the organic semiconductor layer, so that the electrodes are restricted in W/L ratios. However, according to the present invention, electrodes are formed on a different substrate from a substrate having an organic semiconductor layer, so that a wet process can be performed and fine electrodes can be formed without the restriction of W/L ratios.

In the drawings and specification, there have been disclosed typical preferred embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A detector comprising:
a base portion;
first and second electrodes disposed on the base portion and spaced apart from each other;
a reactant layer disposed between the first and second electrodes on the base portion to react with a specific functional group contained in a fluid; and
a protection medium layer surrounding the first and second electrodes and forming a reaction space to expose a portion of the reactant layer.

2. The detector according to claim 1, wherein the protection medium layer forms a conduit-type closed path such that the fluid is allowed to flow.

3. The detector according to claim 1, wherein the base portion comprises:
a third electrode layer; and
an insulating layer disposed on the gate electrode layer and under the first and second electrodes and the reactant layer.

4. The detector according to claim 3, wherein the insulating layer is a dielectric layer.

5. The detector according to claim 1, wherein the reactant layer is an organic semiconductor layer.

6. The detector according to claim 1, wherein the protection medium layer is formed of a polymer.

7. The detector according to claim 1, wherein the protection medium layer is formed of polydimethylsiloxane (PDMS).

8. A method of fabricating a detector, comprising:
forming a lower substrate having a reactant layer which reacts with a specific functional group contained in a fluid;
forming an upper substrate having first and second electrodes for measuring electrical characteristics and a protection medium layer for protecting the first and second electrodes; and
bonding the upper substrate to the lower substrate.

9. The method according to claim 8, wherein the forming of the upper substrate comprises:
depositing the protection medium layer on a frame layer;
forming a reaction space pattern in the protection medium layer; and
forming the first and second electrodes on a portion of the protection medium layer.

10. The method according to claim 8, wherein the forming of the upper substrate comprises:
depositing the protection medium layer on a frame layer having a protrusion for forming a reaction space pattern; and
forming the first and second electrodes on a portion of the protection medium layer.

11. The method according to claim 8, wherein the bonding of the upper substrate to the lower substrate is performed using a lamination process.

12. The method according to claim 11, wherein the forming of the lower substrate comprises:
forming a gate electrode layer;
forming an insulating layer on the gate electrode layer; and
forming the reactant layer on a portion of the insulating layer.

13. The method according to claim 11, wherein the protection medium layer is a PDMS layer.

14. The method according to claim 11, wherein the reactant layer is an organic semiconductor layer.
